(19) United States
(12) Patent Application Publication
(10) Pub. No.: US 2025/0273422 A1
(43) Pub. Date: Aug. 28, 2025

(54) CHARGED PARTICLE BEAM DEVICE

(71) Applicant: Hitachi High-Tech Corporation, Minato-ku, Tokyo (JP)

(72) Inventors: Keigo KASUYA, Tokyo (JP); Shuhei ISHIKAWA, Tokyo (JP); Takashi OHNISHI, Tokyo (JP); Takashi DOI, Tokyo (JP); Kenji TANIMOTO, Tokyo (JP)

(21) Appl. No.: 18/856,773

(22) PCT Filed: Apr. 22, 2022
(86) PCT No.: PCT/JP2022/018553

§ 371 Date: Oct. 14, 2024

(51) Int. Cl. H01J 37/09; H01J 37/073; H01J 37/28

(52) U.S. Cl. CPC H01J 37/09; H01J 37/073; H01J 37/28; H01J 2237/06341

(57) ABSTRACT

The invention provides a charged particle beam device that prevents an electron source from being contaminated and stabilizes an emission current by efficiently reducing the pressure around the electron source. The charged particle beam device includes an electron source that includes a single crystal needle, a filament connected to the single crystal needle, and an insulator that holds the filament, a non-evaporable getter material, an extraction electrode that includes the electron source, holds the non-evaporable getter material, and has a vacuum inside, a vacuum vessel that includes a heater for heating the non-evaporable getter material and the extraction electrode disposed therein, and maintains a vacuum with a pressure higher than that of the vacuum of the extraction electrode, and a shield that is disposed to shield a straight line connecting the single crystal needle, the filament, and the insulator to the non-evaporable getter material, and is connected to the extraction electrode.

### TECHNICAL FIELD

The present invention relates to a charged particle beam device.

### BACKGROUND ART

Charged particle beam devices are devices that irradiate a sample with a charged particle beam, such as an electron beam, and detect secondary electrons, transmitted electrons, back scattered electrons, and X-rays emitted from the sample to generate an observation image of the sample. In order to obtain an observation image with high spatial resolution, a high-brightness electron source is required, and for example, a cold field emission (CFE) electron source is used. In a CFE electron source that emits an electron beam by concentrating an electric field at the distal end of a sharpened single crystal (tip), a residual gas adheres to the distal end of the tip, making an emission current unstable, and thus it is necessary to lower the pressure around the electron source (increase the degree of vacuum).

As a method of lowering the pressure of an electron gun that is equipped with an electron source, a non-evaporable getter (hereinafter, NEG) material may be installed inside the electron gun. Unlike an evaporable getter of the related art, when the NEG material is once heated (activated) in a vacuum, the NEG material absorbs a gas while maintaining its shape without evaporating, and serves as a pump for performing evacuation. PTL 1 discloses a charged particle beam device equipped with an NEG material at a location that is not irradiated with an electron beam.

### CITATION LIST

### Patent Literature

PTL 1: JP2010-10125A

### SUMMARY OF INVENTION

### Technical Problem

However, in PTL 1, there is insufficient consideration given to the deposition of impurities by the NEG material during activation. As a result of the inventors' research, it is found that the NEG material discharges impurities such as carbon compounds to the surroundings during activation, contaminating surrounding structures. At this time, when a tip, filaments, insulators, and the like that constitute an electron source are contaminated, it is not possible to emit electron beams, and the charged particle beam device cannot be used.

Consequently, an object of the invention is to provide a charged particle beam device that prevents an electron source from being contaminated and stabilizes an emission current by efficiently reducing the pressure around the electron source.

### Solution to Problem

In order to achieve the above-described object, the invention provides a charged particle beam device including an electron source that includes a single crystal needle, a filament connected to the single crystal needle, and an insulator that holds the filament, a non-evaporable getter material, an extraction electrode that includes the electron source, holds the non-evaporable getter material, and has a vacuum inside, a vacuum vessel that includes a heater for heating the non-evaporable getter material and the extraction electrode disposed therein, and maintains a vacuum with a pressure higher than that of the vacuum of the extraction electrode, and a shield that is disposed to shield a straight line connecting the single crystal needle, the filament, and the insulator to the non-evaporable getter material, and is connected to the extraction electrode.

Furthermore, in order to achieve the above-described object, the invention provides a charged particle beam device including an electron source that includes a single crystal needle, a filament connected to the single crystal needle, an insulator that holds the filament, and a suppressor that includes the filament and the insulator and has an opening through which a distal end portion of the single crystal needle protrudes, a non-evaporable getter material, an extraction electrode that includes the electron source, the non-evaporable getter material, and a holding part holding the electron source and has a vacuum inside, a vacuum vessel that includes a heater for heating the non-evaporable getter material and the extraction electrode disposed therein and maintains a vacuum with a pressure higher than that of the vacuum of the extraction electrode, and the suppressor and a shield that are arranged to shield a straight line connecting the single crystal needle, the filament, and the insulator to the non-evaporable getter material, in which the shield is connected to the suppressor or the holding part.

Furthermore, the invention provides a charged particle beam device including an electron source that includes a single crystal needle, a filament connected to the single crystal needle, and an insulator that holds the filament, a non-evaporable getter material, an extraction electrode that includes the electron source, the non-evaporable getter material, and a holding part that holds the electron source and has a vacuum inside, a vacuum vessel that includes a heater for heating the non-evaporable getter material and the extraction electrode disposed therein, and maintains a vacuum with a pressure higher than that of the vacuum of the extraction electrode, and a shield that is disposed to shield a straight line connecting the single crystal needle, the filament, and the insulator to the non-evaporable getter material, in which the shield is connected to the holding part.

### Advantageous Effects of Invention

According to the invention, it is possible to provide a charged particle beam device that prevents an electron source from being contaminated and stabilizes an emission current by efficiently reducing the pressure around the electron source.

### BRIEF DESCRIPTION OF DRAWINGS

FIG. 1 is a schematic cross-sectional view showing an example of the overall configuration of a scanning electron microscope, which is an example of a charged particle beam device.

FIG. 2 is a schematic cross-sectional view showing an example of a configuration of a CFE electron source and its surroundings according to Example 1.

FIG. 3 is a schematic cross-sectional view showing an example of an action in which a shield according to Example 1 prevents the CFE electron source from being contaminated.

FIG. 4 is a schematic cross-sectional view showing an example of a configuration of a CFE electron source and its surroundings according to Example 2.

FIG. 5 is a schematic cross-sectional view showing an example of a configuration of a CFE electron source and its surroundings according to Example 3.

FIG. 6 is a schematic cross-sectional view showing an example of an action in which a shield according to Example 3 prevents the CFE electron source from being contaminated.

FIG. 7 is a schematic cross-sectional view showing an example of a configuration of a CFE electron source and its surroundings according to Example 4.

FIG. 8 is a schematic cross-sectional view showing an example of a configuration of a CFE electron source and its surroundings according to Example 5.

FIG. 9 is a schematic cross-sectional view showing an example of a configuration of a CFE electron source and its surroundings according to Example 6.

FIG. 10 is a schematic cross-sectional view showing an example of an action in which a suppressor and a shield according to Example 6 prevent the CFE electron source from being contaminated.

FIG. 11 is a schematic cross-sectional view showing an example of a configuration of a CFE electron source and its surroundings according to Example 7.

FIG. 12 is a schematic cross-sectional view showing an example of a configuration of a CFE electron source and its surroundings according to Example 8.

### DESCRIPTION OF EMBODIMENTS

Hereinafter, examples of a charged particle beam device according to the invention will be described with reference to the accompanying drawings. The charged particle beam device is a device that irradiates a sample with a charged particle beam, such as an electron beam, and detects secondary electrons, transmitted electrons, back scattered electrons, X-rays, and the like emitted from the sample to generate an observation image of the sample.

### Example 1

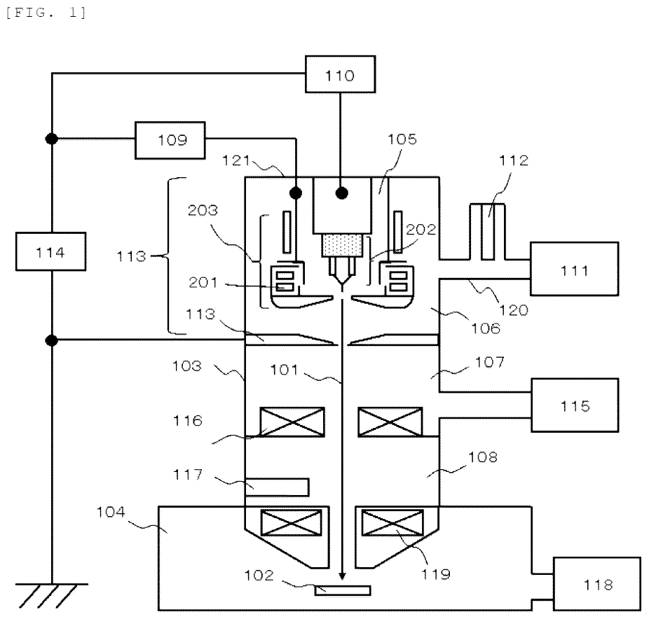

The overall configuration of a scanning electron microscope, which is an example of the charged particle beam device, will be described with reference to FIG. 1. The scanning electron microscope is a device that irradiates a sample 102 with an electron beam 101 and detects secondary electrons and back scattered electrons emitted from the sample to generate an observation image of the sample 102, and includes a column 103 and a sample chamber 104 that maintain a vacuum inside. The column 103 is connected to a ground potential. The inside of the column 103 is divided from the top into a first vacuum chamber 105, a second vacuum chamber 106, a third vacuum chamber 107, and a fourth vacuum chamber 108. An aperture through which the electron beam 101 passes is disposed in the center of an electrode that separates the vacuum chambers, and differential pumping is performed. The vacuum chambers and the sample chamber 104 will be described below.

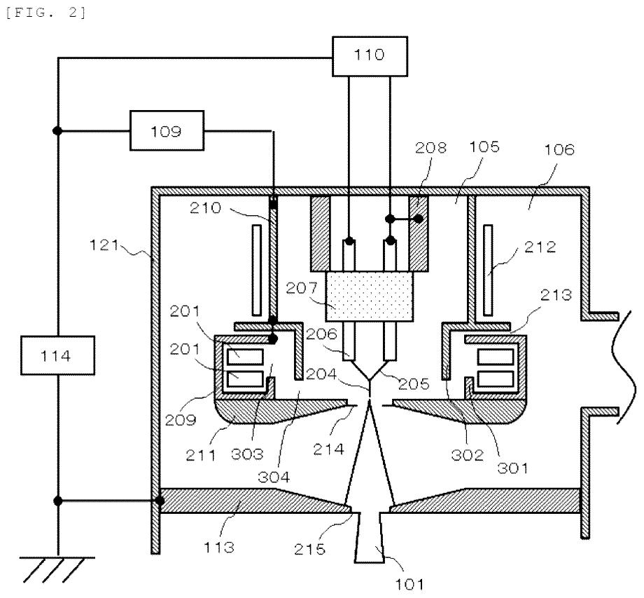

The first vacuum chamber 105 is evacuated by an NEG material 201, and the pressure is made extremely high vacuum of 10⁻⁹ Pa to 10⁻¹⁰ Pa or less. A CFE electron source 202 is disposed in the first vacuum chamber 105, and an extraction electrode 203 is disposed at a position facing the CFE electron source 202. The extraction electrode 203 has a cup shape surrounding the CFE electron source 202, and isolates the first vacuum chamber 105 from the second vacuum chamber 106. An extraction power supply 109 is connected to the extraction electrode 203, and a positive extraction voltage is applied to the CFE electron source 202. The electron beam 101 is emitted from the CFE electron source 202 by the application of the extraction voltage. A flashing power supply 110 is connected to the CFE electron source 202, and a pulse current is applied to a filament at any timing to heat the CFE electron source 202 to approximately 2000° C. (flashing). This operation removes a residual gas adsorbed to the CFE electron source 202 and resets an unstable emission current. Due to the differential pumping, the first vacuum chamber 105 has the lowest pressure compared to the other vacuum chambers. Regarding the pressure in the vacuum chamber, the pressure is higher in the lower vacuum chamber (the vacuum chamber closer to the sample chamber 104). Details of the CFE electron source 202 and the surrounding configurations will be described later with reference to FIG. 2.

The second vacuum chamber 106 is a vacuum chamber surrounded by an electron gun vacuum vessel 121 and an acceleration electrode 113, and is evacuated by an ion pump 111 and an auxiliary NEG pump 112 via a piping 120. The pressure is set to an ultra-high vacuum of approximately 10⁻⁷ Pa to 10⁻⁹ Pa. The acceleration electrode 113 is disposed in the second vacuum chamber 106 and is isolated from the third vacuum chamber 107. The acceleration electrode 113 and the electron gun vacuum vessel 121 are connected to a ground potential. An acceleration power supply 114 is connected to the CFE electron source 202, and a negative acceleration voltage is applied with respect to the ground potential. The electron beam 101 is accelerated at a predetermined speed in accordance with the acceleration voltage. The surface where the extraction electrode 203 and the acceleration electrode 113 face each other has a Butler lens structure to reduce aberration. The configurations above the acceleration electrode 113 are collectively referred to as an electron gun 113.

The third vacuum chamber 107 is evacuated by an ion pump 115. A condenser lens 116 is disposed in the second vacuum chamber 107. The condenser lens 116 condenses the electron beam 101 and adjusts the amount of current, and the like.

A detector 117 is disposed in the fourth vacuum chamber 108. The detector 117 detects secondary electrons and back scattered electrons emitted from the sample 102. A plurality of detectors 117 may be provided, and may be disposed in the sample chamber 104 or another vacuum chamber.

The sample chamber 104 is evacuated by a turbo molecular pump 118. An objective lens 119 and the sample 102 are disposed in the sample chamber 104. The electron beam 101 is condensed by the objective lens 119 and emitted onto the sample 102.

An example of a configuration of the CFE electron source 202 and its surroundings will be described with reference to FIG. 2. The CFE electron source 202 includes a tip 204, a filament 205, two pins 206, and an insulator 207, and is held by a holding part 208. The tip 204 is a tungsten single crystal needle with a sharpened distal end in the <310> or <111> orientation, and the radius of curvature of the distal end is approximately 100 nm. The tip 204 is welded to the distal end of the filament 205. The filament 205 is a tungsten polycrystalline wire formed into a V-shaped hairpin. Pins 206 are welded to both ends of the filament 205. The two pins 206 are metal terminals, and are electrically insulated from each other by being held by the insulator 207. The holding part 208 is a metal cylinder. The tip 204, the filament 205, the pins 206, and the holding part 208 are at the same potential, and an acceleration voltage is applied. The pins 206 are connected to the flashing power supply 110, and the filament 205 is heated by supplying power to perform flashing.

The extraction electrode 203 includes a metal extraction electrode lower part 211, an NEG unit 209, an extraction electrode side part 210, an aperture 214, and the NEG material 201. Stainless steel, titanium, permalloy, and the like are used as a metal material for these. The extraction electrode lower part 211 is disposed at a position facing the distal end of the tip 204 and closest to the tip, and the two are separated from each other by approximately 0.3 mm to 10 mm in the height direction. The extraction electrode lower part 211 is connected to the NEG unit 209 in which the NEG material 201 is disposed. The NEG unit 209 has an opening 303 on the electron source 203 side, and evacuates the first vacuum chamber 105 with the NEG material 201. The NEG material 201 is a porous cylindrical pill made by sintering an alloy of zirconium, vanadium, and iron, and a plurality of NEG materials 201 are disposed. The NEG material 201 may be other NEG materials and may have a shape other than a pill, such as a block, a sheet, a ring, a thin film, or a combination of these, or only one NEG material 201 may be disposed. The NEG material 201 increases the surface area and increases a pumping speed. The aperture 214 is disposed in the center of the extraction electrode lower part 211. The electron beam 101 emitted from the tip 204 passes through the hole of the aperture 214 and proceeds to the second vacuum chamber 106. The electron beam 101 is emitted while spreading in a cone shape, but reaches the acceleration electrode 113 without being shielded by the aperture 214. The hole diameter of the aperture 214 is typically 1 mm or less, more preferably 0.5 mm or less. The extraction electrode lower part 211, the NEG unit 209, the NEG material 201, the extraction electrode side part 210, and the aperture 214 are at the same potential, and an extraction voltage is applied. An electric field at the distal end of the tip 204 is determined by the potential formed by all of these electrodes, and an extraction voltage for obtaining a predetermined emission current is determined.

A heater 212 is disposed on the side of the extraction electrode side part 210 on the second vacuum chamber 106 side. The heater 212 heats the entire extraction electrode 203 to approximately 500° C. once to activate the NEG material 201. The heater 212 is a ceramic heater of such as alumina, and may become a stationary gas emission source. Consequently, the heater 212 is disposed on the second vacuum chamber 106 side to prevent the pressure in the first vacuum chamber 105 from deteriorating.

A aperture 215 is disposed in the center of the acceleration electrode 113. The outer periphery of the electron beam 101 is shielded by the aperture 215 and the acceleration electrode 113, and the central portion thereof proceeds to the third vacuum chamber 107.

The pressure in the vacuum chamber becomes lower as the effective pumping speed of a vacuum exhaust means becomes higher and as the amount of gas discharged from parts in the vacuum chamber decreases. The effective pumping speed becomes higher as a pumping speed of a vacuum pump itself becomes higher and as the conductance of an exhaust path becomes higher. The ion pump 111 and the auxiliary NEG pump 112 have low efficiency in evacuating the surroundings of an electron source because the effective pumping speed is limited by the low conductance of the piping 120. On the other hand, the NEG material 201 is disposed inside the extraction electrode 203 and in the close vicinity of the electron source, and thus the conductance is high and the effective pumping speed is high. For this reason, the surroundings of the electron source can be efficiently evacuated. In addition, since the first vacuum chamber 105 is a narrow space limited only to the inside of the extraction electrode 203, and the number of parts included therein is small, the amount of gas discharged is small. In addition, the entire extraction electrode 203 is heated to a high temperature once by the heater 202, and thus the amount of degassing of the parts themselves (mainly molten hydrogen inside a metal) is also minimized. Due to a synergistic effect of the improvement in the effective pumping speed and the reduction in the amount of gas discharged, the pressure in the first vacuum chamber is efficiently reduced and the emission current of the CFE electron source 202 is stabilized.

A differential pumping port 211 is provided between the NEG unit 209 and the extraction electrode side wall 210, and the first vacuum chamber 105 and the second vacuum chamber 106 are connected to each other. The conductance of the differential pumping port 211 is made low to create a pressure difference of one order of magnitude or more, more preferably two orders of magnitude or more, between the first vacuum chamber 105 and the second vacuum chamber 106. On the other hand, an absorbed gas such as hydrogen discharged during activation of the NEG material 201 is discharged to the second vacuum chamber 106 through a differential pumping port 213, and is discharged by the ion pump 111 and the auxiliary NEG pump 112. By sufficiently removing the gas absorbed by the NEG material 201, the pumping speed and the amount of gas that can be absorbed by the NEG material 201 after activation are increased. In addition, rare gases that cannot be discharged by the NEG material 201 are discharged by the ion pump 111 through the differential pumping port 213. The differential pumping port 213 has a shape such as a circular shape or an elongated hole shape, and typically has a longitudinal width of 5 mm or less and a thickness (hole depth) of 1 mm or more. The aperture 214 also connects the first vacuum chamber 105 and the second vacuum chamber 106, but the conductance of the aperture 214 is extremely low because the hole diameter is small, and the effect is limited.

Another advantage of isolating the first vacuum chamber 105 and the second vacuum chamber 106 and performing differential pumping is that an increase in pressure in the second vacuum chamber 106 is less likely to affect the first vacuum chamber 105. The pressure in the second vacuum chamber 106 may increase due to a gas flowing in from the sample chamber 104, an electron shock desorption gas emitted from the aperture 215 or the acceleration electrode 113 irradiated with the electron beam 101, a sudden electric discharge, or the like. However, due to the effect of the differential pumping, the increase in pressure in the first vacuum chamber 105 is one to two orders of magnitude smaller than the increase in pressure in the second vacuum chamber 106. For this reason, a stable emission current is maintained even when the pressure in the second vacuum chamber 106 deteriorates.

Another advantage of disposing the NEG material 201 inside the extraction electrode 203 is that the electron gun 113 can be made smaller. By efficiently evacuating the surroundings of the electron source with the NEG material 201, the pressure in the first vacuum chamber 105 is maintained low even when the capacity of the ion pump 111 and the auxiliary NEG pump 112 is reduced to increase the pressure in the second vacuum chamber 106. By miniaturizing or omitting the ion pump 111 and the auxiliary NEG pump 112, the electron gun 113 can be made smaller, and it is possible to reduce costs and reduce the floor area or height in which the device is installed. In addition, since the weight of the electron gun 113 is reduced, the resistance of the device to mechanical vibrations and a resolution are improved.

An NEG is a storage type vacuum pump, and the pumping speed thereof decreases when absorbing a gas of a certain value or more. The pumping speed can be restored by activation it, but when activation is repeated a certain number of times, the NEG will reach the end of its life and lose its pumping speed. The NEG material 201 of the invention is assembled together in the NEG unit 209 and has a structure that can be removed as one part. For this reason, when the NEG material 201 reaches the end of its life, a high pumping speed can be obtained again by replacing the NEG unit 209.

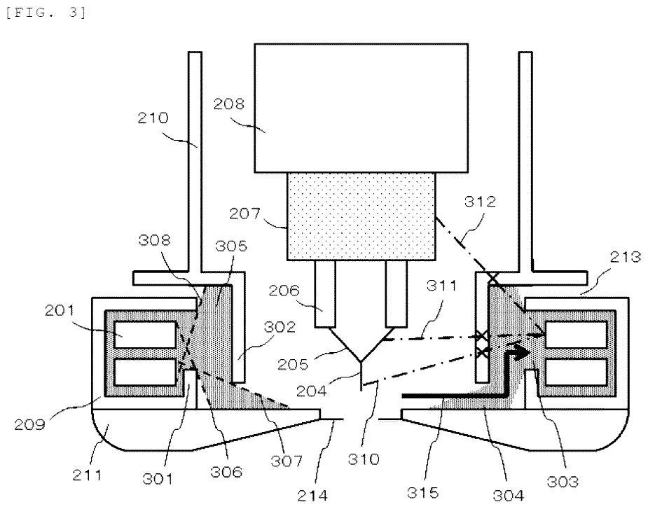

The NEG unit 209 includes a shield 301 that extends from the bottom to the top, and the opening 303 is formed at the top. In addition, the extraction electrode side part 210 includes a shielding electrode 302 that extends from the top to the bottom, and an opening 304 is formed at the bottom. The shield 301 and the NEG unit 209 are integrally made of the same metals and the shield 302 and the extraction electrode side part 210 are integrally made of the same metals, and stainless steel, titanium, permalloy, and the like are used. In addition, they are electrically at the same potential as the extraction electrode 203. The shields 301 and 302 prevent the CFE electron source 202 from being contaminated due to the adhesion of impurities discharged during activation of the NEG material 201. These shields are preferably formed by using materials that reduce the adhesion of impurities. Furthermore, the conductance from the NEG material 201 to the distal end portion of the tip 204 is maintained high, and the effective pumping speed of the NEG material 201 is increased. This action will be described with reference to FIG. 3.

An example of an action in which the shield 301 and the shield 302 prevent the CFE electron source 202 from being contaminated will be described with reference to FIG. 3. The NEG material 201 deposits a carbon compound and the like on the surroundings during activation. When the tip 204 is deposited, the carbon compound cannot be removed even by performing high-temperature flashing, making it impossible to emit electrons. When the filament 205 is deposited, the carbon compound diffuses from the surface of the filament 205 to the distal end of the tip 204, making it impossible to emit electrons. When the insulator 207 is deposited, the carbon compound cannot be electrically insulated because they conduct electricity, making it impossible to perform flashing. For these reasons, when carbon compound is deposited on the tip 204, the filament 205, and the insulator 207, that is, on most of the area of the CFE electron source 202, the electron source becomes unusable.

The carbon compound is discharged linearly from the NEG material 201. Consequently, a shield is disposed such that the CFE electron source 202 is not directly visible from the NEG material 201 to prevent deposition. The carbon compound is discharged from the entire surface of the NEG material 201 toward all solid angles, and a range into which a deposition material scatters is represented by a deposition range 305. Boundary lines 306, 307, and 308 are straight lines representing the trajectory of deposition which is the boundary of the deposition range 305. The shields 301 and 302 limit the solid angles into which the deposition material scatters, thereby narrowing the deposition range 305 and preventing the deposition material from reaching the CFE electron source 202. To express the arrangement of the shields in another expression, it can be said that, when a virtual line is drawn from any point on the NEG material 201 to any points on the tip 204, the filament 205, and the insulator 207 (for example, a virtual line 310, a virtual line 311, a virtual line 312), the shields 301 and 302 are disposed to shield the virtual line. This arrangement prevents deposition on the tip 204, the filament 205, and the insulator 207.

Another effect of the shield is to prevent a potential distribution around the electron source 202 from varying for each electron gun. The NEG material 201 is a porous sintered body, and has a large individual difference in the shape and surface roughness thereof. For this reason, a potential applied to the electron source 202 varies, and an extraction voltage required for electron discharge changes. When the extraction voltage changes, an electronic optical condition for each device changes, resulting in a difference in performance. The difference in performance of the device is a problem in products such as length measurement SEMs in which it is important to obtain the same measurement results with a plurality of devices. An electric field applied to the electron source 202 by the NEG material 201 is shielded by covering the NEG material 201 with the shield 301 and the shield 302. As a result, the potential around the electron source 202 is determined by the shape of the extraction electrode 203 other than the NEG material 202. Since the shape of a metal part can be precisely manufactured by machining, a variation in the potential distribution around the electron source 202 is reduced, and a difference in performance of the device is reduced.

In this example, the positions of the two openings formed by the shields in the height direction are shifted. By providing a plurality of shields and disposing their openings alternately, an exhaust path 315 from the NEG material 201 to the distal end of the tip 204 is shorter than that when there is only one shield. As a result, the conductance is increased, and the effective pumping speed of the NEG material 201 is increased. In order to stabilize the emission current of the electron source 202, it is necessary to lower the pressure, particularly near the distal end portion of the tip 204 from which an electron beam is emitted. Consequently, the opening 304 on the electron source 202 side is disposed at the same height as the tip 204 to shorten the exhaust path 315. On the other hand, the opening 303 on the NEG material 201 side is disposed at a height different from the opening 304 so that the electron source 202 is not directly visible from the NEG material 201. This arrangement method achieves both a high effective pumping speed and prevention of contamination of the electron source, and stabilizes an emission current.

In addition, even when a part of the NEG material 201 is peeled off, the NEG material 201 is covered with the NEG unit 209 and the shield 301, and thus the peeled-off material is prevented from moving to the electron source 202. As a result, electric discharge and damage to the electron source caused by the peeled-off material are prevented.

### Example 2

In Example 1, description has been given of a configuration in which the NEG material is disposed in the extraction electrode to efficiently evacuate the electron source, and the shield prevents the electron source from being contaminated. In Example 2, a configuration in which the position of the opening 304 is different is described. Since some of the configurations and functions described in Example 1 can be applied to Example 2, similar configurations and functions are denoted by the same reference numerals, and the description thereof is omitted.

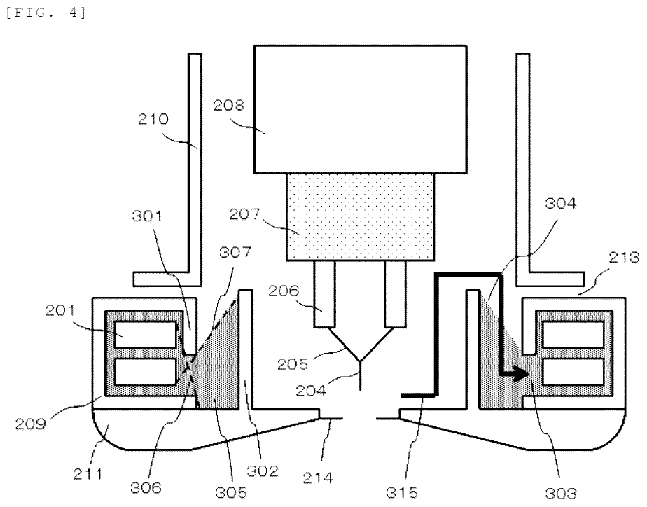

An example of a configuration of the CFE electron source 202 and its surroundings will be described with reference to FIG. 4. In this example, the shield 301 is formed on the upper side of the NEG unit 209, and the opening 303 is formed below the shield 301. The shield 302 is formed integrally with an extraction electrode lower part 211, and the opening 304 is formed between the shield 302 and the NEG unit 209. Even in this configuration, the deposition range 305 is limited by the shield 301 and the shield 302, and deposition on the tip 204, the filament 205, and the insulator 207 is prevented. On the other hand, since the opening 304 on an electron source side is formed above the position of the tip 204, the exhaust path 315 becomes longer, and an effective pumping speed of the NEG material 201 is slightly reduced. Even when the position of the opening is different, both a constant effective pumping speed and prevention of contamination of the electron source are achieved, and an emission current is stabilized.

### Example 3

In Example 2, a configuration in which the position of the opening is different has been described. In Example 3, a configuration in which the accuracy positions of openings in a circumferential direction are different from each other is described. Since some of the configurations and functions described in Examples 1 to 2 can be applied to Example 3, similar configurations and functions are denoted by the same reference numerals, and the description thereof is omitted.

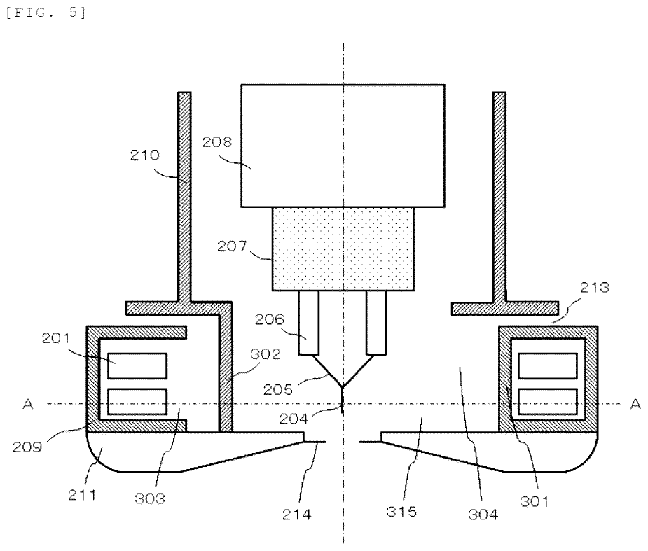

An example of a configuration of the CFE electron source 202 and its surroundings will be described with reference to FIG. 5. In this example, shields 301 and shields 302 are disposed at different positions in the circumferential direction. The NEG unit 209 has a part on the side where the shield 301 is located and a part where the shield 301 is not located. The extraction electrode side part 210 also has a part where the shield 302 is located and a part where the shield 302 is not located. The shields 301 and the shields 302 are disposed alternately, and openings 303 and openings 304 are also disposed alternately.

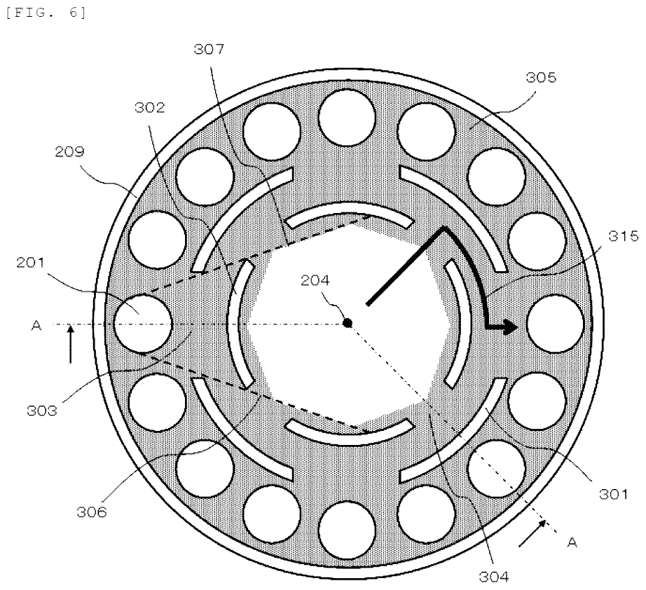

An example of an action in which the shields 301 and the shields 302 prevent the CFE electron source 202 from being contaminated is described with reference to FIG. 6. FIG. 6 is a top view of a cross section A-A in FIG. 5 which is viewed from above. By disposing the shields 301 and 302 at positions with different accuracy in the circumferential direction, the deposition range 305 is limited, and deposition on the tip 204, the filament 205, and the insulator 207 is prevented. Since the position of the opening 304 in the height direction on the electron source side is the same as the height of the tip 204, the exhaust path 315 is short, and the effective pumping speed of the NEG material 201 is high. Even when the openings are disposed at positions with different accuracies in the circumferential direction, both a high effective pumping speed and prevention of contamination of the electron source are achieved, and an emission current is stabilized.

### Example 4

In Example 3, a configuration in which the accuracy positions of the openings in the circumferential direction are different from each other has been described. In Example 4, a configuration in which there is only one shield is described. Since some of the configurations and functions described in Examples 1 to 3 can be applied to Example 4, similar configurations and functions are denoted by the same reference numerals, and the description thereof is omitted.

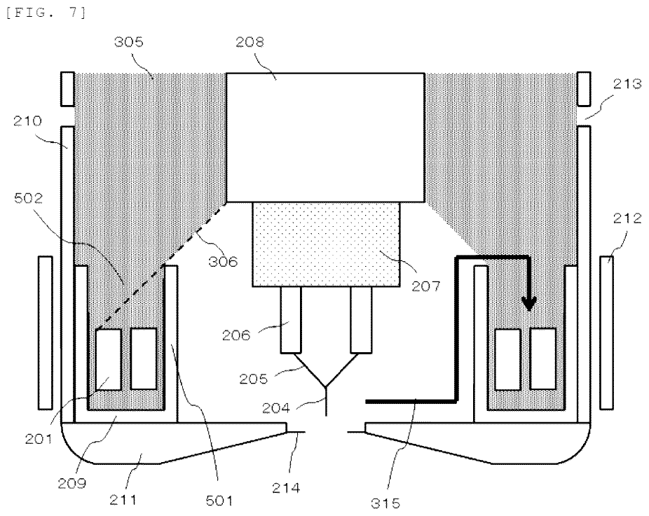

An example of the configuration of the CFE electron source 202 and its surroundings is described with reference to FIG. 7. In this embodiment, the shield is a single shield 501. The shield 501 is created as a side wall of the NEG unit 209, and an opening 502 is formed in the upper part of the NEG unit 209. The short side of the NEG material 201 is arranged facing the opening 502, and the residual gas can easily reach the bottom below, thereby increasing the area that can be adsorbed and improving the pumping speed. The heater 212 may be arranged at the same height as the NEG material 201, and the NEG material 201 may be activated by heating it to a sufficiently high temperature with little power by shortening the path of thermal conduction. The extraction electrode side part 210 and the extraction electrode lower part 211 may be manufactured integrally.

Even if the number of shields is one, the deposition range 305 is limited by the shield 501, and deposition on the tip 204, the filament 205, and the insulator 207 is prevented. By reducing the number of shields, the extraction electrode 203 has a simple shape, and the cost can be reduced. On the other hand, the opening 502 may be formed above the height position of the tip 204, and the exhaust path 315 becomes longer than in Example 1, and the effective pumping speed of the NEG material 201 is slightly reduced. In this example, the lower surface of the NEG unit 209 is connected to the extraction electrode lower part 211, but they do not need to be in contact. The NEG unit 209 may be placed higher and its side surface may be placed on the extraction electrode side part 210. Even in this example, a constant effective pumping speed and prevention of contamination of the electron source are achieved, and the emission current is stabilized.

### Example 5

In Example 4, a configuration in which there is one shield has been described. In Example 5, a configuration in which there is one shield and the position of the opening 502 is different is described. Since some of the configurations and functions described in Examples 1 to 4 can be applied to Example 5, similar configurations and functions are denoted by the same reference numerals, and the description thereof is omitted.

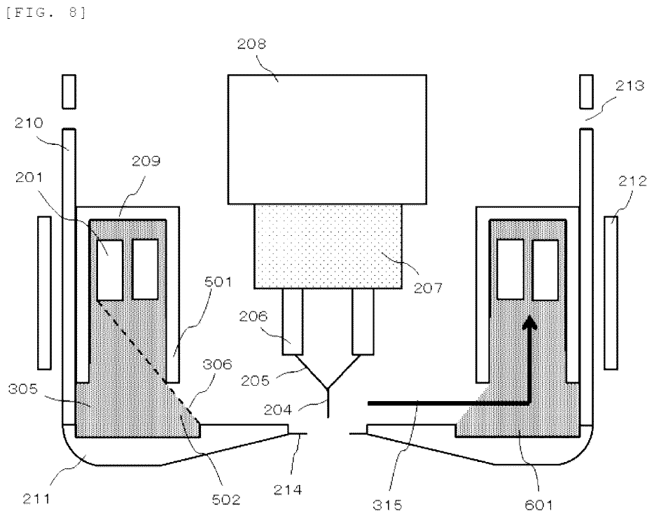

An example of a configuration of the CFE electron source 202 and its surroundings will be described with reference to FIG. 8. In this example, the opening 502 is disposed at the same height as the tip 204. The NEG unit 209 is disposed with its opening facing downward, and the side wall of the NEG unit 209 becomes the shield 501. The opening 502 is formed between the shield 501 and the extraction electrode lower part 211. Since the opening 502 is disposed at the same height as the tip 204, the exhaust path 315 is shorter than that in Example 4, and the conductance is improved. The conductance may be improved by providing a countersunk part 601 in the extraction electrode lower part 211 to increase a cross-sectional area of the exhaust path 315. The countersunk part 601 is formed as a recess with a step provided at the extraction electrode lower part. The countersunk part 601 also prevents a dislodged material of the NEG material 201 from reaching the CFE electron source 202. Even in this example, the deposition range 305 is limited by the shield 501, and deposition on the tip 204, the filament 205, and the insulator 207 is prevented. The simple shape of the extraction electrode 203 can reduce costs, and the effective pumping speed of the NEG material 201 is slightly improved. Also in this example, both a constant effective pumping speed and prevention of contamination of the electron source are achieved, and an emission current is stabilized.

### Example 6

In Example 5, a configuration in which there is one shield and the opening 502 is disposed at the same height as the tip 204 has been described. In Example 6, a configuration including a suppressor is described. Since some of the configurations and functions described in Examples 1 to 5 can be applied to Example 6, similar configurations and functions are denoted by the same reference numerals, and the description thereof is omitted.

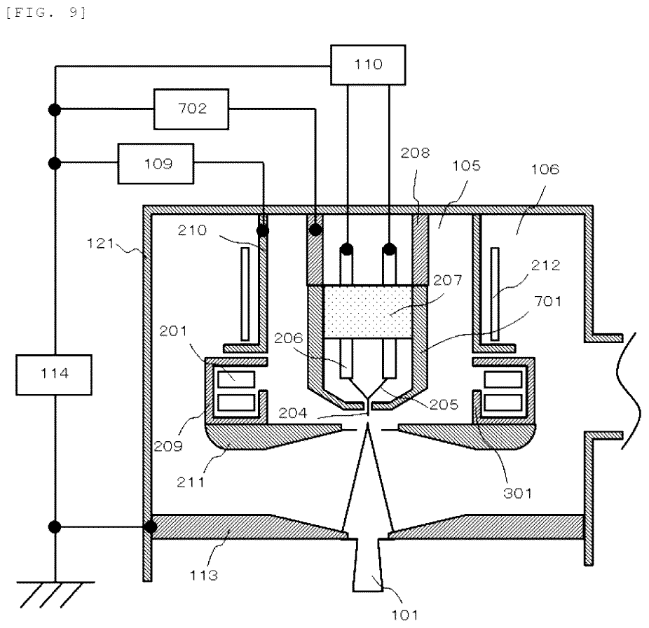

An example of a configuration of the CFE electron source 202 and its surroundings will be described with reference to FIG. 9. In this example, the CFE electron source 202 includes a suppressor 701. The suppressor 701 is fitted to the outside of the insulator 207 and includes the insulator 207, the pin 206, the filament 205, and a part of the tip 204. The suppressor 701 has an opening at the bottom, and a distal end portion of the tip 204 protrudes from the opening. In this manner, the electron source in this example includes the suppressor that includes the filament and the insulator and has the opening from which the distal end portion of a single crystal needle protrudes. The length of the protrusion is approximately 0.1 mm to 1 mm. A suppressor power supply 702 is connected to the suppressor, and a suppressor voltage is applied to the tip 204, which is the potential of an acceleration voltage. The suppressor voltage may be either positive or negative. The suppressor 701 is held by the holding part 208. The holding part 208 is electrically insulated from the pin 206 and is at the potential of the suppressor voltage.

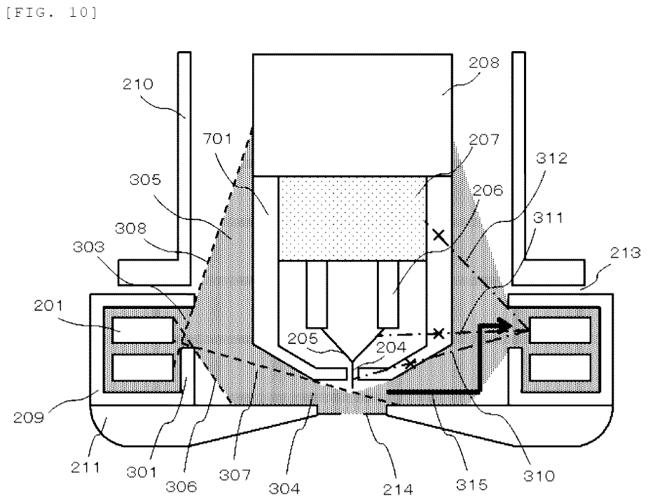

An example of an action in which the suppressor and the shield in this example prevent the CFE electron source 202 from being contaminated will be described with reference to FIG. 10. In this example, the suppressor 701 is one of shields. The shield 301 is manufactured integrally with the NEG unit 209 and has the opening 303 formed in the upper part thereof. The opening 304 is formed between the suppressor 701 and the extraction electrode lower part 211. The openings 303 and 304 are alternately disposed at positions with different heights, and the tip 204, the filament 205, and the insulator 207 are not directly visible from the NEG material 201. A carbon compound deposited from the NEG material 201 is shielded by the shield 301 and the suppressor 701 and is limited to the deposition range 305. As a result, the carbon compound does not reach the tip 204, the filament 205, and the insulator 207, and contamination of these is prevented. To express the arrangement of the shield and the suppressor in another way, it can be said that, when a virtual line is drawn from any point on the NEG material 201 to any points on the tip 204, the filament 205, and the insulator 207 (for example, the virtual line 310, the virtual line 311, the virtual line 312), the shield 301 and the suppressor 701 are arranged to shield the virtual line. As a result of this arrangement, deposition on the tip 204, the filament 205, and the insulator 207 is prevented.

The opening 304 on the CFE electron source 202 side in this example is disposed at the same height as the tip 204. For this reason, the exhaust path 315 is short and the conductance is high. In addition, since the suppressor 701 serves as a shield, the number of shields provided on the extraction electrode 203 side can be reduced, realizing simplification of the extraction electrode and a reduction in costs. Also in this example, both a high effective pumping speed and prevention of contamination of the electron source are achieved, and an emission current is stabilized.

### Example 7

In Example 6, a configuration including a suppressor has been described. In Example 7, a configuration in which an NEG unit is provided in an application unit of an acceleration voltage is described. Since some of the configurations and functions described in Examples 1 to 6 can be applied to Example 7, similar configurations and functions are denoted by the same reference numerals, and the description thereof is omitted.

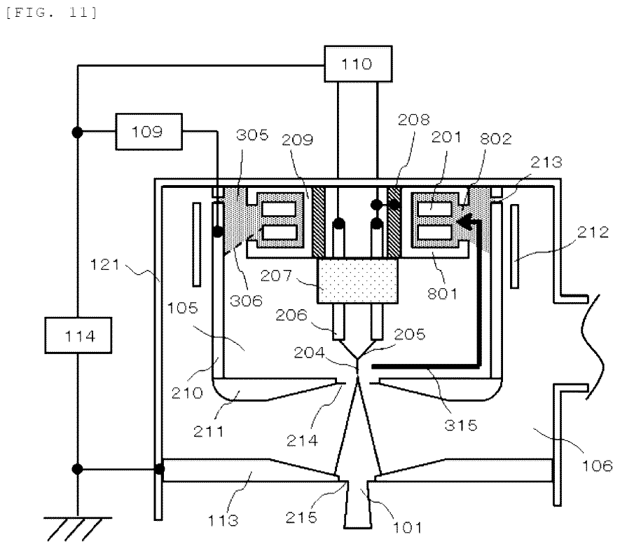

An example of a configuration of the CFE electron source 202 and its surroundings will be described with reference to FIG. 11. In this example, the NEG unit 209 is connected to the side of the holding part 208. The lower surface of the NEG unit 209 serves as a shield 801, and the NEG unit 209, the shield 801, the holding part 208, and the NEG material 201 are at the potential of an acceleration voltage. An opening 802 is formed on the side of the NEG unit 209. The NEG material 201 is shielded by the shield 801, and the tip 204, the filament 205, and the insulator 207 are not directly visible. For this reason, a carbon compound deposited from the NEG material 201 is shielded by the shield 801 and limited to the deposition range 305. As a result, the CFE electron source 202 is not deposited.

Even in this example, an electric field applied to the electron source 202 by the NEG material 201 is shielded by the shield 801. As a result, the potential around the electron source 202 is determined by the shapes of the extraction electrode side part 210, the extraction electrode lower part 211, and the aperture 214, and a difference in performance of the device due to an individual difference of the NEG material 201 is eliminated. In addition, even when a part of the NEG material 201 is peeled off, the peeled-off part remains inside the NEG unit 209 and is prevented from falling. As a result, electric discharge and damage to the electron source caused by the peeled-off material are prevented. In addition, when the electron beam 101 collides with the aperture 214, the extraction electrode lower part 211, the aperture 215, or the acceleration electrode 113, back scattered electrons are generated. These back scattered electrons may further repeat collisions and reflections and dissipate inside a first vacuum chamber 106. However, since the NEG material 201 is at the same potential as the CFE electron source 202, most of the back scattered electrons do not have enough energy to collide with the NEG material 201. As a result, gas emission caused by electrons colliding with the NEG material is suppressed.

Since the opening 802 is disposed above the tip 204, the exhaust path 315 is increased, and the effective pumping speed of the NEG material 201 is slightly reduced. Even in this example, both a constant effective pumping speed and prevention of contamination of the electron source are achieved, and an emission current is stabilized.

### Example 8

In Example 7, a configuration in which the NEG unit is provided in the application unit of an acceleration voltage has been described. In Example 8, a configuration in which an NEG unit is provided in an application unit of a suppressor voltage is described. Since some of the configurations and functions described in Examples 1 to 7 can be applied to Example 8, similar configurations and functions are denoted by the same reference numerals, and the description thereof is omitted.

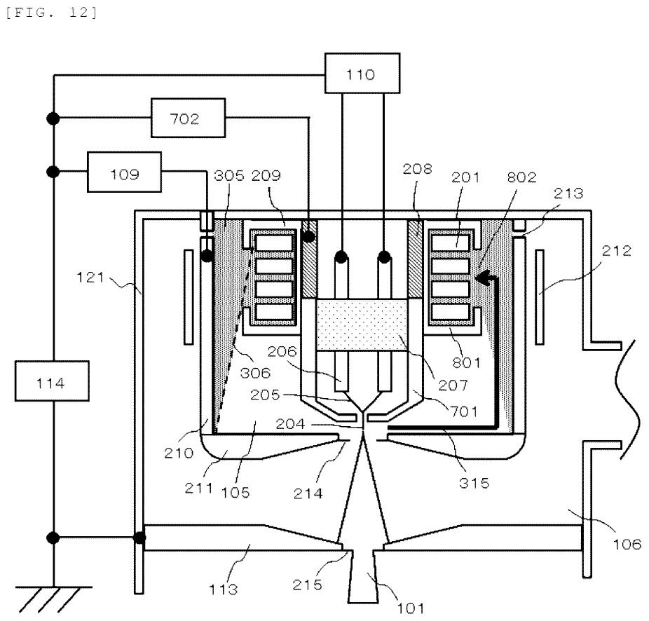

An example of a configuration of the CFE electron source 202 and its surroundings will be described with reference to FIG. 12. In this example, the NEG unit 209 is connected to the side of the suppressor 701 or the holding part 208. The lower surface of the NEG unit 209 serves as the shield 801, and the NEG unit 209, the shield 801, the holding part 208, the NEG material 201, and the suppressor 701 are at the potential of a suppressor voltage. The opening 802 is formed on the side of the NEG unit 209. The NEG material 201 is shielded by the shield 801, and the tip 204, the filament 205, and the insulator 207 are not directly visible. For this reason, a carbon compound deposited from the NEG material 201 is shielded by the shield 801 and limited to the deposition range 305. As a result, the CFE electron source 202 is not deposited.

Also in this example, the shield 801 shields an electric field applied to the electron source 202 by the NEG material 201, and a difference in performance of the device due to an individual difference of the NEG material 201 is eliminated. In addition, even when a part of the NEG material 201 is peeled off, the peeled-off part is prevented from falling, and electric discharge and damage to the electron source are prevented. In addition, when the suppressor voltage is negative, the NEG material 201 has a potential lower than that of the CFE electron source 202 even when the electron beam 101 generates back scattered electrons, and thus collision of the back scattered electrons cannot occur. For this reason, gas emission caused by electrons colliding with the NEG material is suppressed.

The NEG unit 209 may be manufactured integrally with the suppressor 701. In this case, the NEG material 201 can be replaced at the same time when regular maintenance for replacing the CFE electron source 202 is performed. As a result, a pumping speed of the NEG material 201 can be restored and maintained at a high level with less work and cost.

Since the opening 802 is disposed above the tip 204, the exhaust path 315 is increased, and the effective pumping speed of the NEG material 201 is slightly reduced. Even in this example, both a constant effective pumping speed and prevention of contamination of the electron source are achieved, and an emission current is stabilized.

The plurality of examples of the invention have been described above. The invention is not limited to the above examples, and the components can be modified and embodied within the scope of the invention. For example, instead of tungsten single crystal, a low work function material such as CeB₆ or LaB₆ or a material with an inactive surface such as a carbon-coated material may be used as the tip 204. In addition, a nanowire electron source with a sharpened distal end having a curvature radius of several tens of nm or several atoms to approximately one atom, or a single-atom electron source may be used. In addition, the invention is not limited to the CFE electron source and can also be applied to Schottky electron sources. In order to obtain a stable emission current from a Schottky electron source, an ultra-high vacuum of 10⁻⁷ Pa or less is required. By applying the invention, efficient evacuation around the electron source can be achieved, and both an ultra-high vacuum and a compact electron gun can be achieved. In addition, the influence of a rise in pressure in a second vacuum chamber is reduced, making it easier to maintain a stable emission current.

The plurality of components disclosed in the above examples may be appropriately combined. Furthermore, some components may be omitted from all of the components described in the above examples.

### REFERENCE SIGNS LIST

101: electron beam
102: sample
103: column
104: sample chamber
105: first vacuum chamber
106: second vacuum chamber
107: third vacuum chamber
108: fourth vacuum chamber
109: extraction power supply
110: flashing power supply
111: ion pump
112: auxiliary NEG pump
113: acceleration electrode
114: acceleration power supply
115: ion pump
116: condenser lens
117: detector
118: turbo molecular pump
119: objective lens
120: piping
121: electron gun vacuum vessel
201: NEG material
202: CFE electron source
203: extraction electrode
204: tip
205: filament
206: pin
207: insulator
208: holding part
209: NEG unit
210: extraction electrode side part
211: extraction electrode lower part
212: heater
213: differential pumping port
214: aperture
215: aperture
301: shield
302: shield
303: opening
304: opening
305: deposition range
306: boundary line
307: boundary line
308: boundary line
310: virtual line
311: virtual line
312: virtual line
315: exhaust path
501: shield
502: opening
601: countersunk part
701: suppressor
702: suppressor power supply
801: shield
802: opening

1. A charged particle beam device comprising:
an electron source that includes a single crystal needle, a filament connected to the single crystal needle, and an insulator that holds the filament;
a non-evaporable getter material;
an extraction electrode that includes the electron source, holds the non-evaporable getter material, and has a vacuum inside;
a vacuum vessel that includes a heater for heating the non-evaporable getter material and the extraction electrode disposed therein, and maintains a vacuum with a pressure higher than that of the vacuum of the extraction electrode; and
a shield that is disposed to shield a straight line connecting the single crystal needle, the filament, and the insulator to the non-evaporable getter material, and is connected to the extraction electrode.

2. The charged particle beam device according to claim 1, wherein the shield is a member that reduces adhesion of a deposition material from the non-evaporable getter material to the electron source.

3. The charged particle beam device according to claim 2, wherein a plurality of the shields are disposed.

4. The charged particle beam device according to claim 3, wherein a plurality of openings are formed in the shield, and positions of the openings disposed on the electron source side and the NEG material side differ in a height direction.

5. The charged particle beam device according to claim 3, wherein a plurality of openings are formed in the shield, and positions of the openings disposed on the electron source side and the NEG material side differ in a circumferential direction.

6. The charged particle beam device according to claim 4, wherein the position of the opening disposed on the electron source side in the height direction among the openings is the same as the height of the single crystal needle.

7. The charged particle beam device according to claim 2, wherein an opening is formed in the shield, and the position of the opening disposed on the electron source side in the height direction is the same as the height of the single crystal needle.

8. The charged particle beam device according to claim 2, wherein the extraction electrode includes a countersunk part on a surface facing the electron source.

9. The charged particle beam device according to claim 2, wherein the heater is connected to the outside of the extraction electrode.

10. The charged particle beam device according to claim 2, wherein a plurality of the non-evaporable getter materials are stored in one sub-assembly that is detachable from the extraction electrode.

11. The charged particle beam device according to claim 2, wherein the electron source includes a suppressor that includes the filament and the insulator and has an opening through which a distal end portion of the single crystal needle protrudes.

12. A charged particle beam device comprising:
an electron source that includes a single crystal needle, a filament connected to the single crystal needle, an insulator that holds the filament, and a suppressor that includes the filament and the insulator and has an opening through which a distal end portion of the single crystal needle protrudes;
a non-evaporable getter material;
an extraction electrode that includes the electron source, the non-evaporable getter material, and a holding part holding the electron source and has a vacuum inside;
a vacuum vessel that includes a heater for heating the non-evaporable getter material and the extraction electrode disposed therein and maintains a vacuum with a pressure higher than that of the vacuum of the extraction electrode; and
the suppressor and a shield that are arranged to shield a straight line connecting the single crystal needle, the filament, and the insulator to the non-evaporable getter material,
wherein the shield is connected to the suppressor or the holding part.

13. A charged particle beam device comprising:
an electron source that includes a single crystal needle, a filament connected to the single crystal needle, and an insulator that holds the filament;
a non-evaporable getter material;
an extraction electrode that includes the electron source, the non-evaporable getter material, and a holding part that holds the electron source and has a vacuum inside;
a vacuum vessel that includes a heater for heating the non-evaporable getter material and the extraction electrode disposed therein, and maintains a vacuum with a pressure higher than that of the vacuum of the extraction electrode; and
a shield that is disposed to shield a straight line connecting the single crystal needle, the filament, and the insulator to the non-evaporable getter material,
wherein the shield is connected to the holding part.
